(19) United States
(12) Patent Application Publication
(10) Pub. No.: US 2007/0212892 A1
(43) Pub. Date: Sep. 13, 2007

(54) Method of forming semiconductor device structures using hardmasks

(76) Inventors: Dirk Caspary, Dresden (DE); Stefano Parascandola, Dresden (DE)

Correspondence Address: EDELL, SHAPIRO & FINNAN, LLC, 1901 RESEARCH BLVD., SUITE 400, ROCKVILLE, MD, 20850, US

(21) Appl. No.: 11/588,429

(22) Filed: Oct. 27, 2006

Related U.S. Application Data
(63) Continuation-in-part of application No. 11/369,013, filed on Mar. 7, 2006.

(30) Foreign Application Priority Data
Apr. 26, 2006 (DE) 102006019413.6

(51) Int. Cl. H01L 21/302

(52) U.S. Cl. 438/736; 257/E21.258

(57) ABSTRACT

A first hardmask layer is provided over a substrate, and a second hardmask layer is provided over the first hardmask layer. The second hardmask layer is patterned to form a second hardmask structure having sidewalls. A sacrificial layer of a sacrificial material is conformally deposited such that the deposited sacrificial layer has substantially horizontal and vertical portions. The horizontal portions of the sacrificial layer are removed to form lines of the sacrificial material adjacent to the sidewalls of the second hardmask lines. The sacrificial layer is at least partially removed to structure the sacrificial material and the remaining sacrificial layer is used to structure the first hardmask. The second hardmask structures is removed to uncover portions of the first hardmask. Uncovered portions of the substrate are etched, thereby forming structures in the substrate below the first hardmask.

### CROSS-REFERENCE TO RELATED APPLICATIONS

This application is a Continuation-in-Part of U.S. application Ser. No. 11/369,013, filed on Mar. 7, 2006, and titled “A Memory Device, An Array Of Conductive Lines, and Methods Of Making The Same,” the entire contents of which are hereby incorporated by reference.

### BACKGROUND

Semiconductor memory devices typically comprise arrays of memory cells that are arranged in rows and columns. The gate electrodes of rows of memory cell transistors are connected by word lines, by which the memory cells are addressed. The word lines usually are formed by patterning a conductive layer stack so as to form single word lines which are arranged in parallel. The word lines are electrically insulated from one another laterally by a dielectric material. The lateral distance between two word lines and the width of a word line sum to the pitch of the array of word lines. The pitch is the dimension of the periodicity of a periodic pattern arrangement. The word lines succeed one another in a completely periodic fashion to reduce the required device area as much as possible. Likewise, the bit lines are formed by patterning a conductive layer so as to form the single bit lines.

An example of a non-volatile memory device is based on the NROM technology. FIG. 1A shows a cross-sectional view of an NROM cell between I and I as is shown in FIG. 1B. Generally, the NROM cell is an n-channel MOSFET device, wherein the gate dielectric is replaced with a storage layer stack 46. As is shown in FIG. 1A, the storage layer stack 46 is disposed above the channel 43 and under the gate electrode 44. The storage layer stack 46 comprises a silicon nitride layer 202 which stores the charge and two insulating silicon dioxide layers 201, 203 which sandwich the silicon nitride layer 202. The silicon dioxide layers 201, 203 have a thickness greater than 2 nm to avoid any direct tunneling. In the NROM cell shown in FIG. 1A, two charges are stored at each of the edges adjacent the n-doped source/drain regions 41, 42.

The NROM cell is programmed by channel hot electron injection (CHE), for example, whereas erasing is accomplished by hot hole enhanced tunneling (HHET), by applying appropriate voltages to the corresponding bit lines and word lines, respectively.

FIG. 1B shows a plan view of an exemplary memory device comprising an array 100 of a NROM cells. To be more specific, the memory cell array 100 comprises bit lines 4 extending in a first direction as well as word lines 2 extending in the second direction. Memory cells 45 are disposed between adjacent bit lines at each point of intersection of a substrate portion with a corresponding word line 2. The first and second source/drain regions 41, 42 form part of corresponding bit lines. The gate electrodes 44 form part of a corresponding word line. At a point of intersection of the word lines and bit lines, the bit lines and the word lines are insulated from each other by a thick silicon dioxide layer (not shown). In order to minimize the area required for the memory cell array 100, it is desirable to reduce the width of the word lines as much as possible. Nevertheless, for contacting the single word lines landing pads 111 having a minimum area are required. Usually, these landing pads 111 are disposed in a fan-out region 110 adjacent the memory cell array 100. In order to achieve a contact having an appropriate contact resistance, the area of each of the landing pads 111 must have a minimum value. In the peripheral portion 120, the transistors for controlling the action of the memory cell array are disposed. In particular, word line drivers, sense amplifiers and other transistors are disposed in the peripheral portion 120. Usually, the peripheral portion 120 is formed in the CMOS technology. Due to the special programming method for injecting a charge into the memory cells, the transistors disposed in the peripheral portion 120 have to withstand higher voltages than the transistors disposed in the array portion. As a consequence, the channel length of the corresponding transistors in the peripheral portion amount to approximately 0.25 μm and higher. In particular, this channel length cannot be reduced to achieve a reduced area of the peripheral portion 120 and, thus, the memory device.

As is shown in FIG. 1B, the word lines 2 have a minimum width wmin and a minimum distance dmin from each other. In order to increase the package density of such a memory cell array, it is desirable to reduce the width and the distance of the word lines. However, when shrinking the width of the word lines 2, a minimum contact area in the fan-out region 110 should be maintained. In addition, if the word line array is patterned by using a photolithography technique that is usually employed, the lateral dimensions of the word lines as well as the distance between neighboring word lines is limited by the minimal structural feature size which is obtainable by the technology used. A special problem arises if the landing pads and the array of conductive lines are to be patterned by one single lithographic step. In more detail, the area of the landing pads should be large, whereas the distance and the size of the conductive lines should be small. However, a lithographic step for simultaneously image different ground rules is very difficult to implement. Hence, a patterning method is sought by which it is possible to simultaneously pattern structures having a different ground rule.

### SUMMARY

A method for forming a structure of a semiconductor device involves providing a layer stack with a first hardmask layer over a substrate and a second hardmask over the first hardmask. The second hardmask layer is patterned to form a second hardmask structure having sidewalls, and a sacrificial layer of a sacrificial material is conformally deposited such that the deposited sacrificial layer has substantially horizontal and vertical portions. The horizontal portions of the sacrificial layer are removed to form lines of the sacrificial material adjacent to the sidewalls of the second hardmask lines. The sacrificial layer is at least partially removed to structure the sacrificial material, and the remaining sacrificial layer is used to structure the first hardmask. The second hardmask structures are removed to uncover portions of the first hardmask, and the uncovered portions of the layer stack are etched to form structures in the substrate.

The above and still further features and advantages of the present invention will become apparent upon consideration of the following detailed description of specific embodiments thereof, wherein like numerals define like components in the drawings.

### BRIEF DESCRIPTION OF THE DRAWINGS

FIG. 1A shows a cross-sectional view of an NROM cell.

FIG. 1B shows a plan view of a memory device comprising NROM cells.

FIG. 2 shows a cross-sectional view of a substrate after patterning a photoresist layer.

FIG. 3 shows a cross-sectional view of the substrate after patterning a hardmask layer.

FIG. 4 shows a cross-sectional view of the substrate after thinning the hardmask lines.

FIG. 5 shows a cross-sectional view of the substrate after depositing a sacrificial layer.

FIG. 6A shows a cross-sectional view of the substrate after patterning a photoresist layer.

FIG. 6B shows a plan view of the substrate after patterning the photoresist layer.

FIG. 7A shows a cross-sectional view of the substrate after performing an etching step.

FIG. 7B shows a plan view of the substrate after performing the etching step.

FIG. 8A shows a cross-sectional view of the substrate after removing the hardmask material.

FIG. 8B shows a plan view of the substrate after removing the hardmask material.

FIG. 9A shows a cross-sectional view of the substrate after patterning a photoresist layer.

FIG. 9B shows a plan view of the substrate after patterning the photoresist layer.

FIG. 10A shows a cross-sectional view of the substrate after performing an etching step.

FIG. 10B shows a plan view of the substrate after performing the etching step.

FIG. 11 shows a cross-sectional view of the substrate after performing a further etching step.

FIG. 12A shows a cross-sectional view of the memory device according to the present invention.

FIG. 12B shows a plan view of a memory device according to the present invention.

FIG. 13 shows a plan view of a memory device according to another embodiment of the present invention.

FIG. 14 shows a plan view of an array of conductive lines according to an embodiment of the present invention.

FIG. 15 shows for a different embodiment of the present invention a plan view (i.e. a top view) of a part of a structure to be manufactured having a random pattern.

FIG. 16 shows a cross section through a layered stack with a first hardmask and a second hardmask and a structured photoresist layer.

FIG. 17 shows a cross section through the layered stack after the pattering of the second hardmask.

FIG. 18 shows a cross section through the layered stack after the conformal depositing of a sacrificial layer on the second hardmask.

FIG. 19 shows a cross section after the horizontal parts of the sacrificial layer has been removed.

FIG. 19A shows a top view of the second hardmask, the rims of the hardmask lined with sacrificial material.

FIG. 20 shows a cross section of the layered stack with the second hardmask removed.

FIG. 20A shows a top view of the remaining parts of the sacrificial layer after removal of the second hardmask.

FIG. 21 shows a cross section of the layered stack with a further photoresist layer to pattern the structure made of sacrificial material.

FIG. 21A shows a top view of the partially by photoresist covered structure made of sacrificial material.

FIG. 22 shows a cross section with the remaining parts of the sacrificial layer.

FIG. 22A shows a top view with the remaining parts of the sacrificial layer.

FIG. 23 shows a cross section with another patterned photoresist layer for the pattering below lying layers.

FIG. 23A shows a top view of the patterned photoresist layer.

FIG. 24 shows a cross section of the patterned first hardmask layer.

FIG. 24A shows a top view of the pattering first hardmask layer.

FIG. 25 shows a cross section of the patterned first hardmask layer.

### DETAILED DESCRIPTION

As described below in detail, an improved memory device comprises: a semiconductor substrate having a surface; a plurality of first conductive lines extending in first direction; a plurality of second conductive lines extending in a second direction; a plurality of memory cells, each being accessible by addressing corresponding ones of the first and second conductive lines, the memory cells being at least partially formed in the semiconductor substrate; and a plurality of landing pads made of a conductive material, each of the landing pads being connected with a corresponding one of the second conductive lines. The plurality of second conductive lines comprises first and second subsets of conductive lines, the conductive lines of the first subset alternating with the conductive lines of the second subset. The landing pads connected with the second conductive lines of the first subset are disposed on a first side of each of the second conductive lines, and the landing pads connected with the second conductive lines of the second subset are disposed on a second side of each of the second conductive lines, the first side being opposite to the second side.

Accordingly, the conductive lines and the landing pads can be arranged such that two landing pads are arranged in a space between two neighboring conductive lines, whereas in a subsequent space between neighboring conductive lines no landing pad is arranged.

Moreover, the landing pads which are connected with two neighboring conductive lines can be arranged so as to be disposed on the opposite sides of the conductive lines.

For example, the first conductive lines can correspond to bit lines and the second conductive lines correspond to word lines of the memory device, the word lines being disposed above the bit lines.

Moreover, the landing pads can be arranged in a staggered fashion with respect to the second direction.

In addition, the landing pads can be arranged with an increasing distance with respect to a reference position of the memory device, the distance being measured along the second direction.

By way of example, two neighboring landing pads which are connected to two adjacent second conductive lines are disposed at the same height, the height being measured in the first direction with respect to a reference position.

For example, the landing pads can be disposed on one side of the plurality of second conductive lines.

Alternatively, the landing pads can be disposed on two opposite sides of the plurality of second conductive lines.

Another described embodiment involves an array of conductive lines formed on or at least partially in a semiconductor substrate, the array comprising: a plurality of conductive lines extending in a first direction; and a plurality of landing pads made of a conductive material, each of the landing pads being connected to a corresponding one of the conductive lines. The plurality of conductive lines comprises first and second subsets of conductive lines, the conductive lines of the first subset alternating with the conductive lines of the second subset. The landing pads connected to the conductive lines of the first subset are disposed on a first side of each of the conductive lines, and the landing pads connected to the conductive lines of the second subset are disposed on a second side of each of the conductive lines, the first side being opposite to the second side.

The landing pads can be arranged in a staggered fashion with respect to the first direction. For example, the landing pads can be disposed on one side of the plurality of conductive lines. Alternatively, the landing pads can be disposed on two opposite sides of the plurality of conductive lines.

The width of each of the conductive lines can be less than 150 nm or even less than 100 nm, the width being measured perpendicularly with respect to the first direction. By way of example, the width of each of the landing pads can be less than 150 nm, the width being measured perpendicularly with respect to the first direction. Moreover, the length of each of the landing pads can be less than 150 nm, the length being measured with respect to the first direction.

An exemplary method of forming a memory device comprises: providing a semiconductor substrate having a surface; forming a plurality of first conductive lines on the surface of the semiconductor substrate, the first conductive lines extending in a first direction; forming a plurality of second conductive lines extending in a second direction, the second direction intersecting the first direction; and forming a plurality of memory cells, each memory cell being accessible by addressing corresponding ones of the first and second conductive lines. The plurality of first or second conductive lines are formed by: forming a layer stack comprising at least one conductive layer; forming a hardmask layer and patterning the hardmask layer to form hardmask lines having sidewalls; conformally depositing a sacrificial layer of a sacrificial material such that the deposited sacrificial layer has horizontal and vertical portions; removing the horizontal portions of the sacrificial layer so as to form lines of the sacrificial material adjacent the sidewalls of the hardmask lines; removing the hardmask lines to uncover portions of the layer stack; and etching the uncovered portions of the layer stack thereby forming single conductive lines.

After removing the hardmask lines two adjacent lines of the sacrificial material can be connected with each other. The method may further comprise etching the line of the sacrificial material at a predetermined position so as to isolate two adjacent lines of the sacrificial material.

The method can further comprise removing selected lines of the sacrificial material which is performed before etching the uncovered portions of the layer stack.

By removing selected lines of the sacrificial material, pairs of connected lines of the sacrificial material can be removed. The method can further include etching the line of the sacrificial material at a predetermined position so as to isolate two adjacent lines of the sacrificial material. For example, the removal of selected lines of the sacrificial material and the etching of the line of the sacrificial material can be performed by a simultaneous etching operation.

The method may further comprise patterning the sacrificial layer to form pads of the sacrificial material, the pads being adjacent the lines of the sacrificial material. For example, patterning the sacrificial layer to form pads of the sacrificial material may include etching the sacrificial layer.

For example, the pads of the sacrificial material can be defined so that two pads of the sacrificial material are disposed between two adjacent hardmask lines.

By way of example, the hardmask layer may comprise silicon dioxide and the sacrificial material may comprise silicon.

According to a further aspect, a method of forming an array of conductive lines comprises: providing a semiconductor substrate having a surface; and providing a plurality of first conductive lines on the surface of the semiconductor substrate, the first conductive lines extending in a first direction. The plurality of first conductive lines are formed by: providing a layer stack comprising at least one conductive layer; providing a hardmask layer and patterning the hardmask layer to form hardmask lines having sidewalls; conformally depositing a sacrificial layer of a sacrificial material such that the deposited sacrificial layer has horizontal and vertical portions; removing the horizontal portions of the sacrificial layer so as to form lines of the sacrificial material adjacent the sidewalls of the hardmask lines; removing the hardmask lines so as to uncover portions of the layer stack; and etching the uncovered portions of the layer stack thereby forming single conductive lines.

In addition, the method may comprise patterning the sacrificial layer to form pads of the sacrificial material, the pads being adjacent the lines of the sacrificial material.

For example, the pads of the sacrificial material may be defined in a final region of the array of conductive lines.

By way of example, all the pads of the sacrificial material can be defined in a final region which is disposed on one side of the array of conductive lines.

Alternatively, all the pads of the sacrificial material are defined in final regions which are disposed on opposite sides of the array of conductive lines.

Also described below is an exemplary method for forming a structure of a semiconductor device comprising a substrate, a first hardmask layer under a second hardmask layer and a layer stack. The method involves: patterning the second hardmask layer to form a second hardmask structures having sidewalls; conformally depositing a sacrificial layer of a sacrificial material such that the deposited sacrificial layer has horizontal and vertical portions; removing the horizontal portions of the sacrificial layer to form lines of the sacrificial material adjacent the sidewalls of the second hardmask lines; removing at least partially the sacrificial layer for structuring the sacrificial material and using the remaining sacrificial layer for structuring the first hardmask; removing the second hardmask structures to uncover portions of the first hardmask; and etching the uncovered portions of the layer stack thereby forming structures in stack below the first hardmask.

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated, as they become better understood by reference to the following detailed description. The elements of the drawings are not necessarily to scale relative to each other. Like reference numerals designate corresponding similar parts.

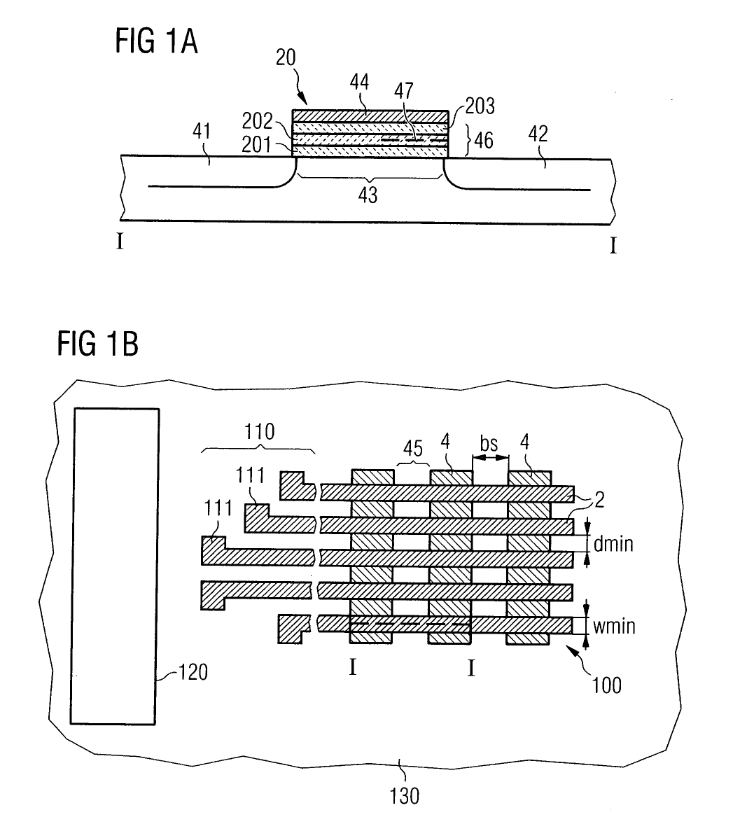

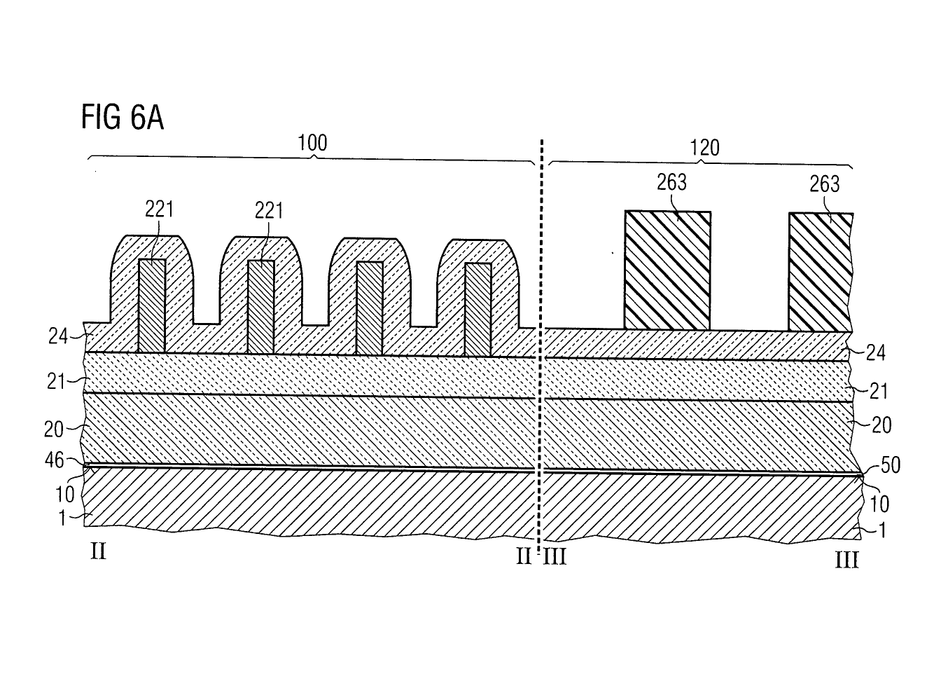

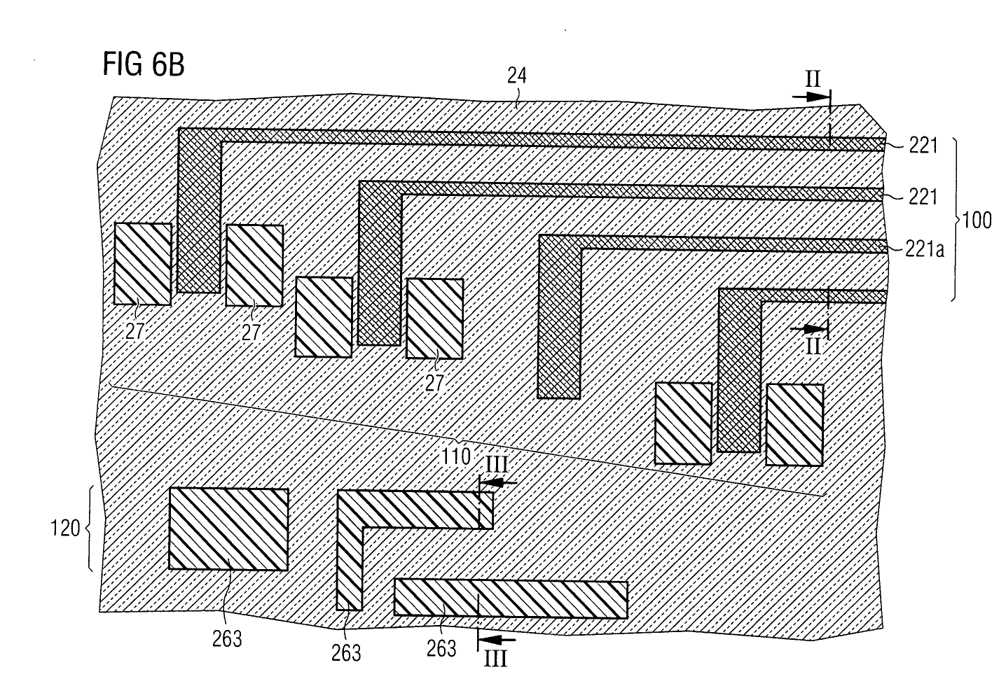

In the following FIG. 1-14 cross-sectional views, the left-hand portion shows the cross-sectional view of the array portion 100, whereas the right-hand portion shows the cross-sectional view of the peripheral portion 120. In particular, the left-hand portion is taken between II and II, whereas the right-hand portion is taken between III and III as is, for example, illustrated in FIG. 6B.

Starting point for performing the method of the present invention is a semiconductor substrate, in particular, a silicon substrate, which is, for example, p-doped. In the substrate portion in which the peripheral portion of the memory device is to be formed, a gate oxide layer 50 is grown by thermal oxidation. In the array portion, after depositing a storage layer stack comprising a first SiO₂ layer having a thickness of 1.5 to 10 nm, a Si₃N₄ layer having a thickness of 2 to 15 nm followed by a second SiO₂ layer having a thickness of 5 to 15 nm, the storage layer stack is patterned so as to form lines. After covering the lines with a protective layer and forming spacers adjacent the sidewalls of the lines of the layer stack, an implantation step is performed so as to define the source/drain regions in the exposed portions.

A bit line oxide is provided by performing a deposition step, followed by a step of depositing a word line layer stack. These steps are well known to the person skilled in the art of NROM devices, and a detailed description thereof is omitted.

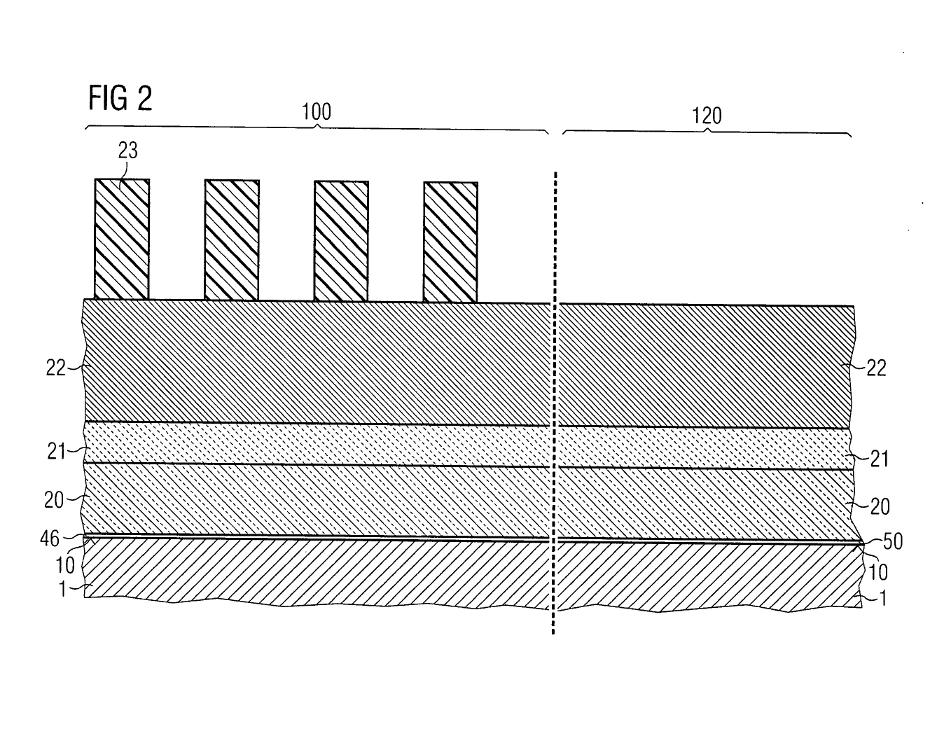

As is shown in FIG. 2, as a result, on the surface 10 of the semiconductor substrate 1, in particular, a p-doped semiconductor substrate, in the array portion 100, the storage layer stack 46, a word line layer stack 20, a silicon nitride cap layer 21 and a hardmask layer 22 are disposed. The word line layer stack 20 usually comprises segments of a first polysilicon layer and a second polysilicon layer having a total thickness of approximately 70 to 110 nm, followed by a titanium layer (not shown), a tungsten nitride layer having a thickness of approximately 5 to 20 nm and a tungsten layer having a thickness of approximately 50 to 70 nm. On top of the tungsten layer, the silicon nitride layer 21 having a thickness of approximately 120 to 180 nm is disposed. On top of the silicon nitride layer 21, the hardmask layer 22 is disposed. In the present embodiment, the hardmask layer 22 is made of silicon dioxide, which can, for example, be formed by a deposition method using TEOS (tetraethylorthosilicate) as a starting material. The hardmask layer 22 can have a thickness of approximately 40 to 100 nm.

In the peripheral portion 120 the same layer stack is disposed on the silicon substrate 1, with the peripheral gate oxide layer 50 being disposed instead of the storage layer stack 46. In particular, the thickness of the peripheral gate oxide layer 50 can be different from the thickness of the storage layer stack 46 in the array portion.

A photoresist layer 23 is deposited on the resulting surface in the array portion 100 as well as in the peripheral portion 120 and patterned so as to form single lines which are disposed in a periodic manner. The resulting structure is shown in FIG. 2, wherein a patterned photoresist layer 23 is shown. In particular, the photoresist layer 23 is patterned in a lines/spaces pattern. The pitch of the lines/spaces pattern, i.e., the sum of the line width and the space width, should be approximately twice the line width to be achieved.

As is commonly used, an antireflective coating (ARC) layer may be disposed on top of the hardmask layer. Instead of the silicon dioxide layer, any other suitable material can be used as the material of the hardmask layer. For example, the hardmask layer can also be made of carbon. In particular, if carbon is taken as the hardmask material, it is necessary to deposit an SiON layer on top of the carbon layer in order to enable the resist strip. In addition, the ARC layer can be disposed beneath the photoresist layer.

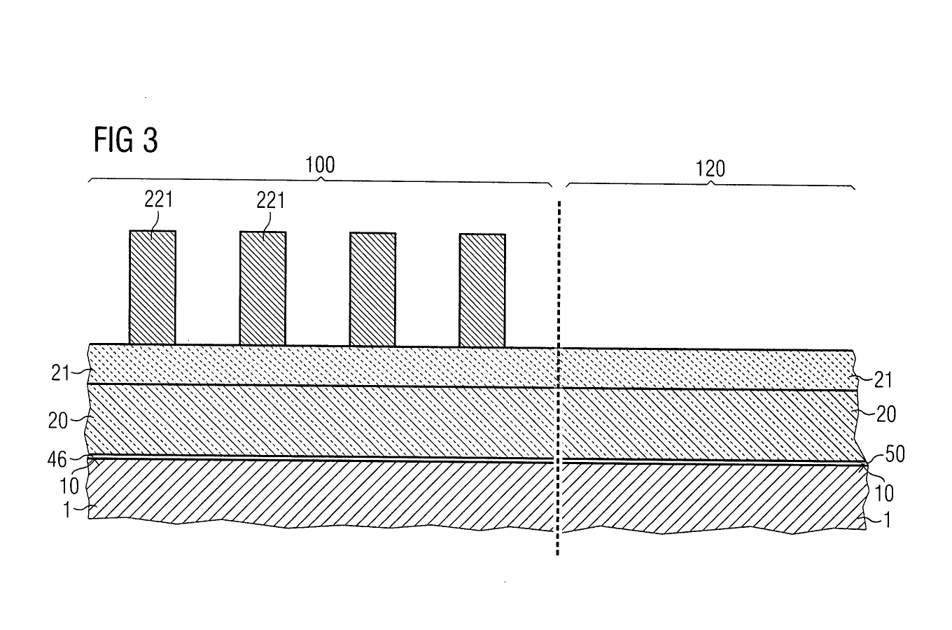

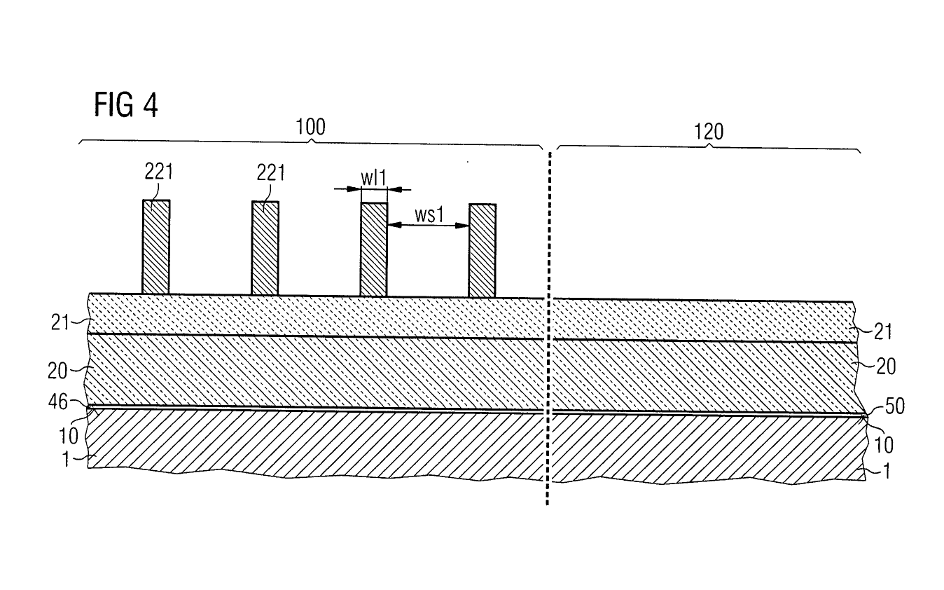

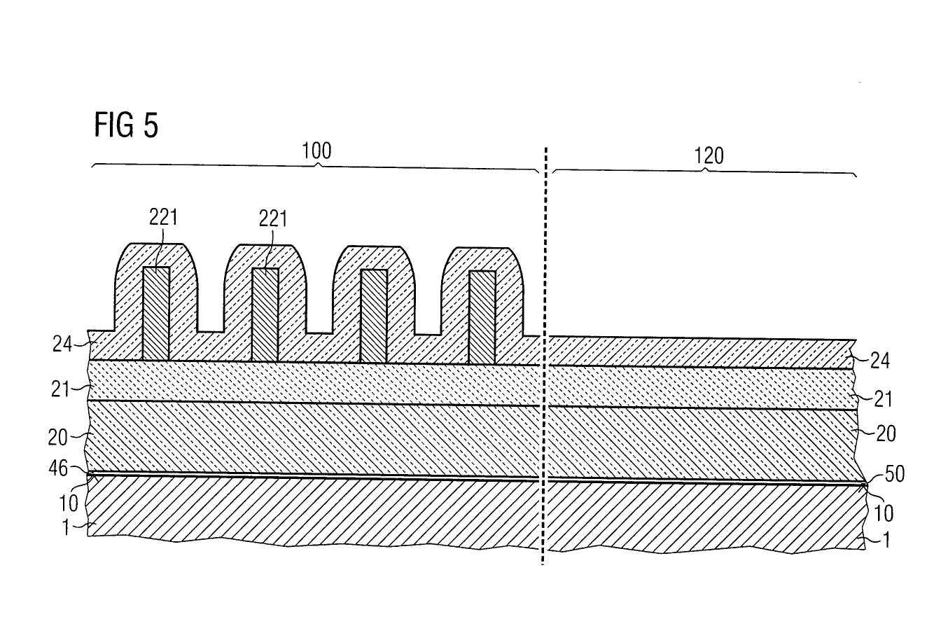

In the next step, the photoresist pattern is transferred to the hardmask layer 22. In particular, an etching step is performed, taking the photoresist mask as an etching mask. After removing the photoresist material 23, the structure shown in FIG. 3 is obtained, wherein single lines 221 of the hardmask material 22 are formed. Stated differently, for obtaining the structure shown in FIG. 3, starting from the structure shown in FIG. 2, the SiO₂ layer 22 is etched at the uncovered portions and, thereafter, a resist stripping step is performed. For further reducing the line width of the silicon dioxide lines 221, an oxide recess step can be performed so as to reduce the line width of the silicon dioxide lines 221. Alternatively, the photoresist material can be exposed by an over-exposing step in the step which has been described with reference to FIG. 2, so as to obtain a line width w11 of each of the lines which is smaller than the width ws1 of the spaces between adjacent lines. A cross-sectional view of the resulting structure is shown in FIG. 4.

Referring to FIG. 5, in the next step, a sacrificial layer 24 is deposited on the resulting surface. In particular, the sacrificial layer 24 can be made of polysilicon. The material of the sacrificial layer can be arbitrarily chosen, with the proviso that the sacrificial layer should be able to be etched selectively with respect to the cap layer of the word line layer stack, the cap layer usually being made of silicon nitride. In addition, the sacrificial layer 24 must be able to be etched selectively with respect to the hardmask material 22. The thickness of the sacrificial layer should be approximately equal to the target width (CD “critical dimension”) of the resulting word lines, incremented by approximately 10 nm. For example, if a target CD of the word line of 50 nm is to be achieved, the thickness of the sacrificial layer should be about 60 nm. Alternatively, if the target width of the word lines is to be about 25 nm, the thickness of the sacrificial layer should be approximately 35 nm. Nevertheless, the optimum thickness of the sacrificial layer depends on the minimal structural feature size F of the technology employed. As can be seen from FIG. 5, the sacrificial layer 24 is conformally deposited so as to cover the lines 221 in the array portion, while forming a planar layer in the peripheral portion 120. The materials of the sacrificial layer as well as of the hardmask layer can be arbitrarily selected. However, it is necessary to select a hardmask material which can be etched selectively with respect to the material of the sacrificial layer and the material of the word line cap layer 21.

Referring next to FIGS. 6A and 6B, a photoresist layer 26 is then deposited and patterned. Consequently, the array portion 100 is uncovered, whereas in the peripheral portion peripheral photoresist pads 263 are formed. A cross-sectional view of the resulting structure is shown in FIG. 6A, whereas a plan view on the resulting structure is shown in FIG. 6B. As can be further seen, in addition, photoresist pads 27 are formed adjacent the vertical portions of the sacrificial layer 24 in the fan-out region 110. Landing pads are to be formed at those portions which are covered by the photoresist pads 27.

As can be seen from FIG. 6B, the structure comprises an array portion 100, in which the word lines are to be formed. In particular, lines 221 of the hardmask material as well as the vertical portions of the sacrificial layer 24 are formed. In the fan-out region 110, photoresist pads 27 are defined. Moreover, a peripheral portion 120 is defined at the peripheries of the resulting memory device.

As can further be gathered from FIG. 6B, the photoresist pads 27 are patterned in a manner so that no photoresist pads 27 are defined adjacent one selected line 221a of the hardmask material. This is the region of the memory array, in which the word lines are to be removed in a later process step. Moreover, the photoresist pads 27 are disposed in the spaces between neighboring hardmask lines 221.

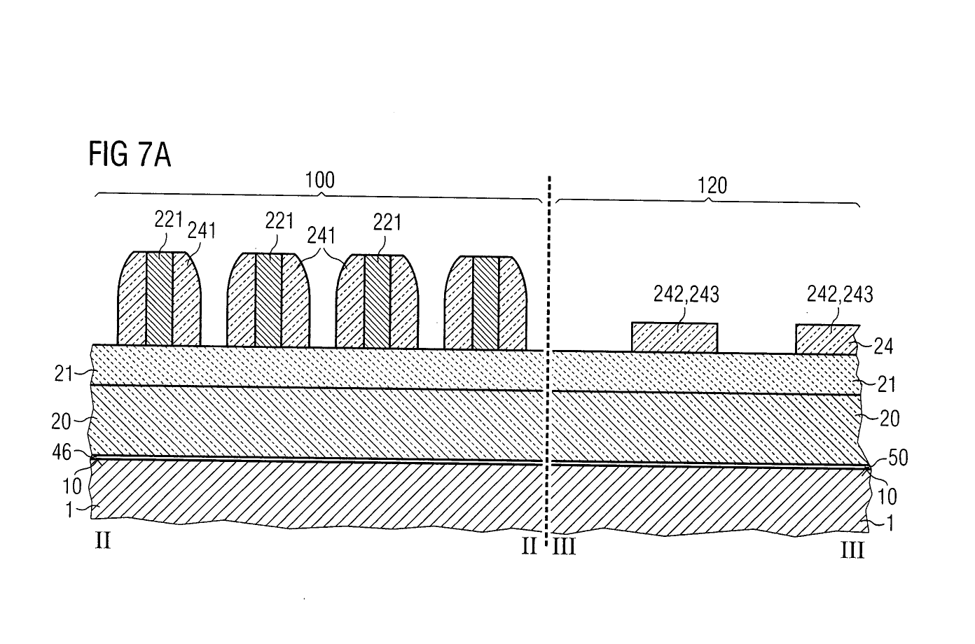

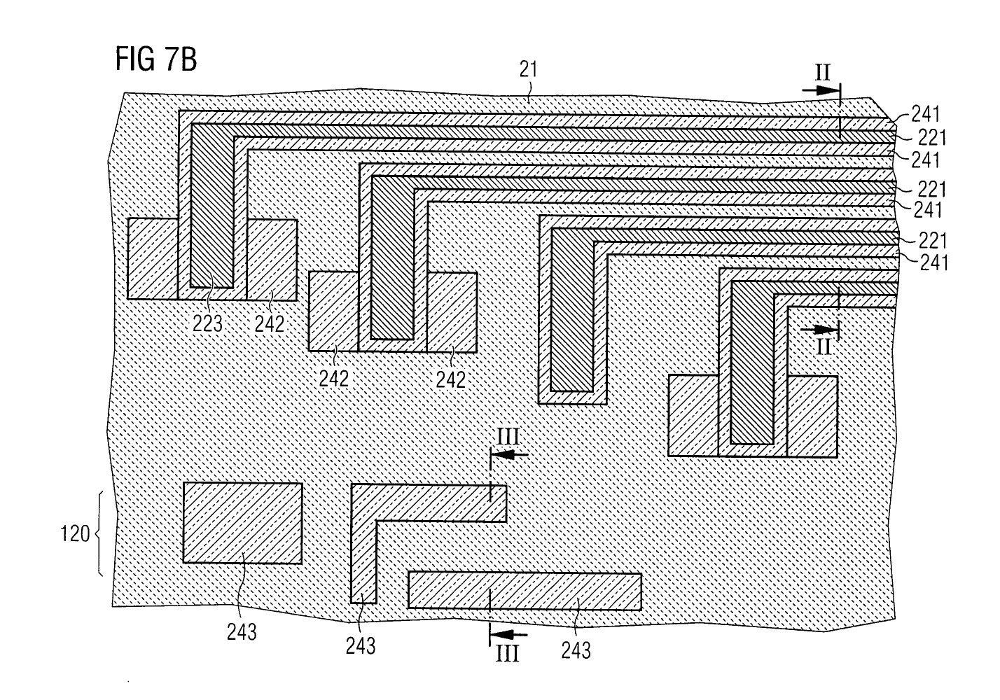

Referring to FIGS. 7A and 7B, the horizontal portions of the sacrificial layer 24 next are etched. Consequently, spacers 241 of the sacrificial layer are formed in the array portion adjacent the vertical sidewalls 220 of the hardmask lines 221. In other words, the spacers 241 of polysilicon are formed adjacent the hardmask lines 221. In addition, in the peripheral portion as well as in the fan-out region the polysilicon layer is not removed from the portions, which are covered by the photoresist material 26.

FIG. 7A shows the resulting structure after removing the photoresist material. As can be seen from the left hand portion, which shows the array portion, spacers 241 are formed adjacent the sidewalls 220 of the hardmask lines 221. In addition, in the peripheral portion, polysilicon pads 242 as well as peripheral polysilicon pads 243 are formed.

FIG. 7B shows a plan view on the resulting structure. As can be seen, lines of the sacrificial layer 241 are formed so that two adjacent lines 241 are connected at a final region 223 of the lines 221 of the hardmask material. At the final region 223 of the lines 221 of the hardmask material, polysilicon pads 242 are formed. In the spaces between adjacent hardmask lines, two polysilicon pads 242 are disposed. Each of the two polysilicon pads 242 is assigned to different polysilicon spacers 241. Landing pads for contacting the resulting word lines are to be formed at the position of these polysilicon pads 242. In addition, peripheral polysilicon pads 243 are formed. The polysilicon material 242, 243 and 241 is isolated by means of the cap layer of the word line layer stack 21, which can in particular be made of silicon nitride.

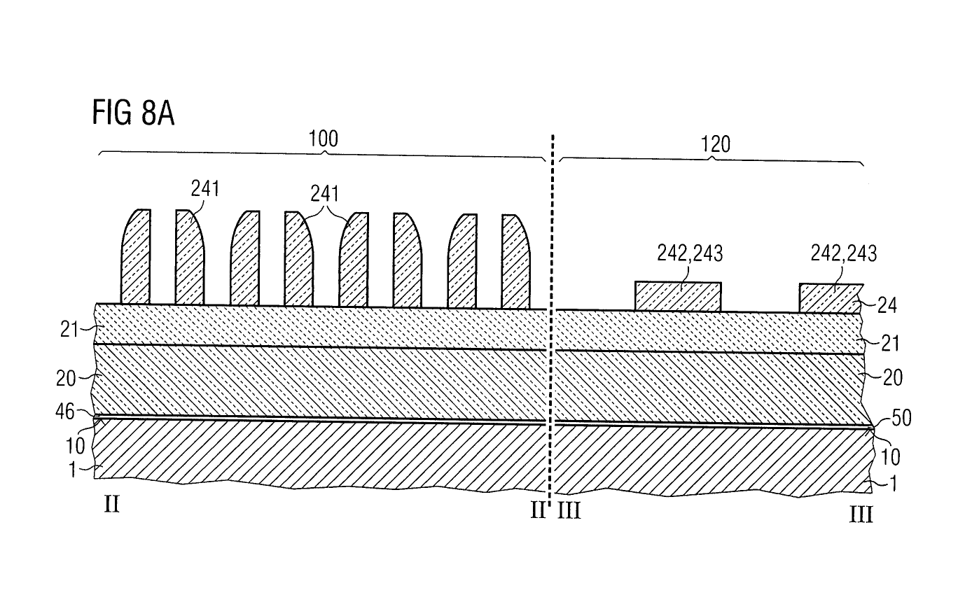

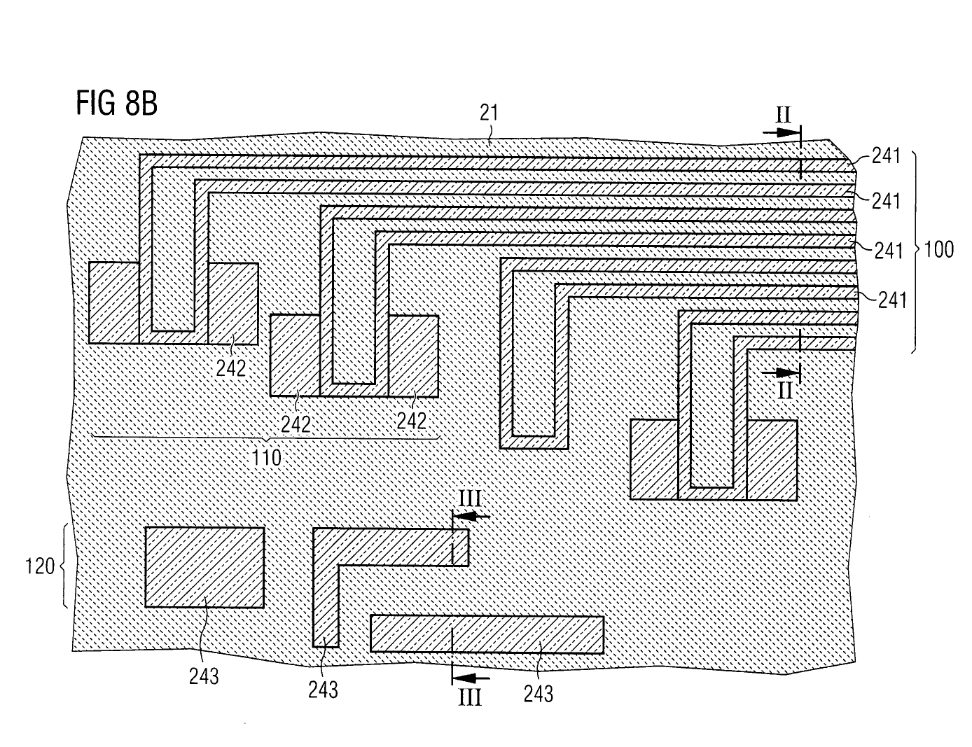

Referring now to FIGS. 8A and 8B, the hardmask material 22 is then removed, for example by wet etching. Optionally, the spaces between neighboring spacers 241 of the sacrificial material can be filled with the hardmask material, followed by a planarizing step, before performing the step of removing the hardmask material. In this case, an attack of the etchant on the silicon nitride cap layer 21 is advantageously avoided.

After removing the hardmask material 22, as a result, isolated spacers 241 which are made of the sacrificial material remain on the surface of the cap nitride layer 21 in the array portion 100. The peripheral portion remains unchanged. The resulting structure is shown in FIG. 8A. A plan view on the resulting structure is shown in FIG. 8B. As can be seen, single lines 241 which are made of polysilicon are formed in the array portion. Moreover, in the fan-out region 110 polysilicon pads 242 are formed, and in the peripheral portion peripheral polysilicon pads 243 are formed. As can further be seen, adjacent pairs of the sacrificial spacers 241 are connected with each other. The cap nitride material 21 is disposed between the single polysilicon portions. In order to separate adjacent lines 241 of the sacrificial material, another photolithographic step is performed so as to isolate the lines 241 from each other and, in addition, to remove selected spacers, so that, as a result, selected word lines will be removed in a later process step.

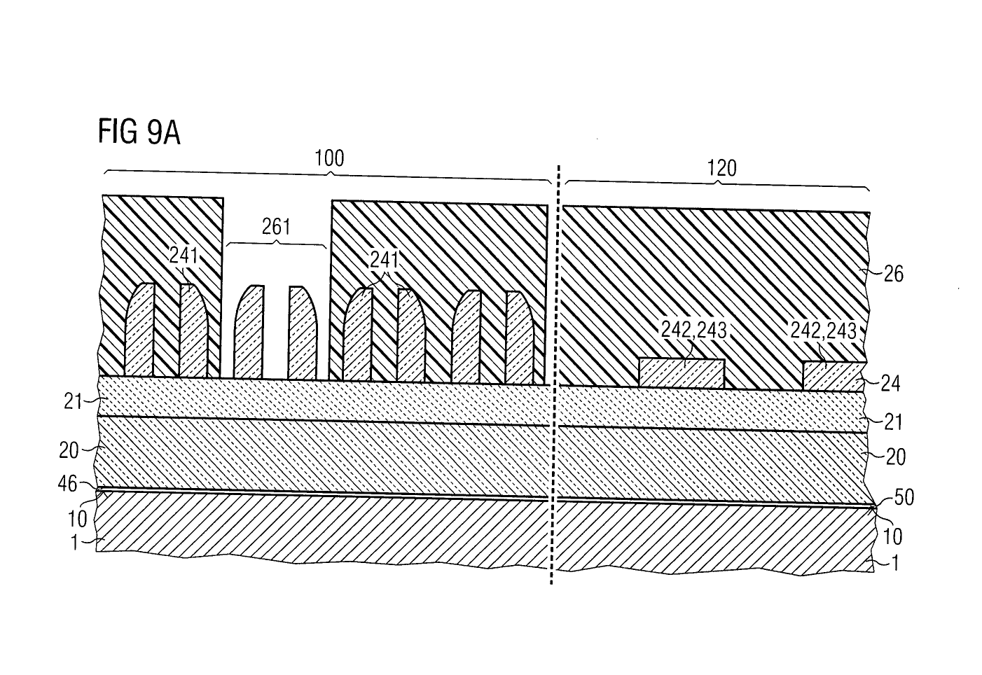

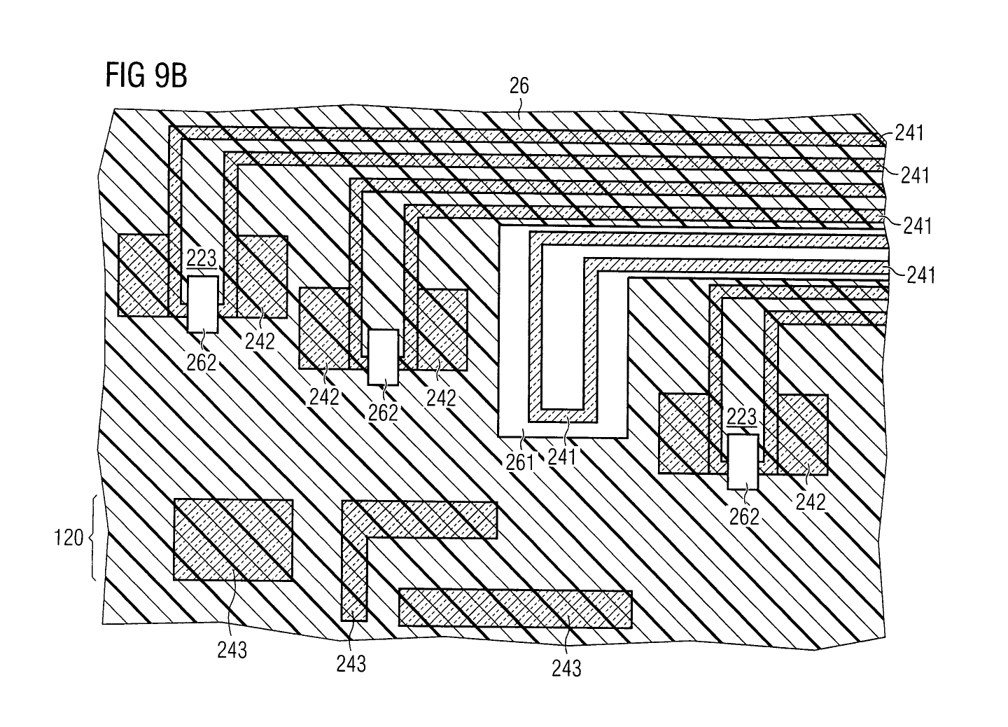

To this end, as shown in FIGS. 9A and 9B, the entire surface of the memory device is covered with a further photoresist layer 26 and is patterned in the array portion as well as in the fan-out region 110. In particular, array openings 261 are formed at those positions, at which spaces between selected word lines are to be formed. Moreover, fan-out openings 262 are formed at the final regions 223. FIG. 9A shows a cross-sectional view of the resulting structure. As can be seen, array openings 261 are formed at predetermined positions. Moreover, FIG. 9B shows a plan view on the resulting structure. As can be seen, an array opening 261 is formed at a position corresponding to a pair of spacers 241. Moreover, a fan-out opening 262 is formed between adjacent polysilicon pads 242.

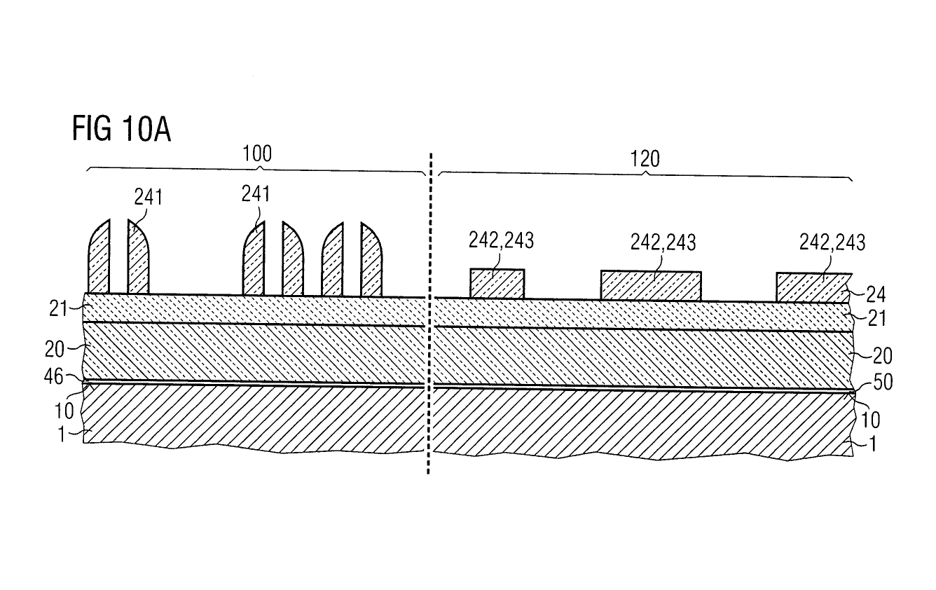

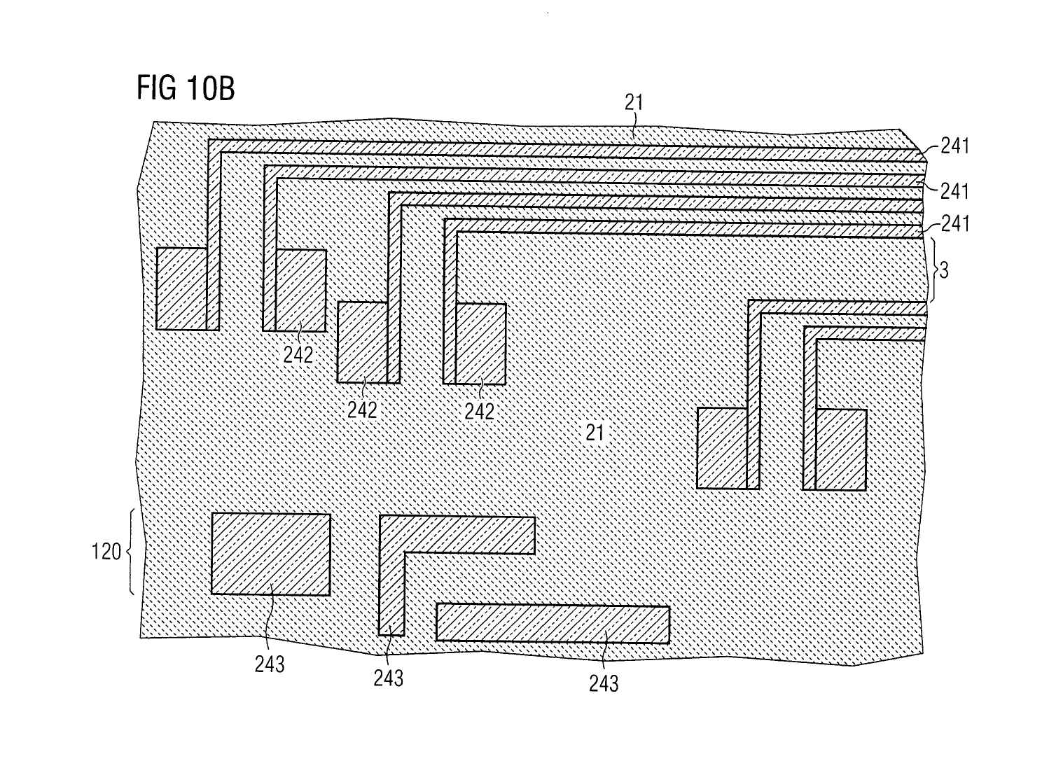

In the next step, an etching step for etching polysilicon is performed so as to remove the uncovered portions of the polysilicon spacer 241. FIG. 10A shows a cross-sectional view of the resulting structure after removing the photoresist material 26. As can be seen, polysilicon pads 242 and peripheral polysilicon pads 243 are formed in the peripheral portion 120, whereas in the array portion 100 selected spacers 241 are removed.

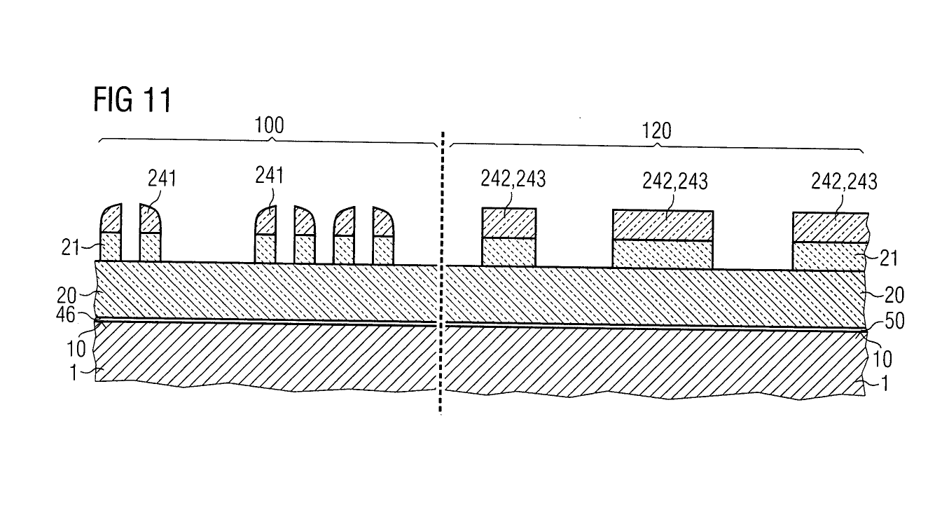

FIG. 10B shows a plan view on the resulting structure. As can be seen, the spacers 241 have been removed from the word line removal region 3. In addition, adjacent spacers 241 are now isolated from each other. In the next step, an etching step for etching the cap nitride layer 21 is performed, resulting in the structure shown in FIG. 11. More specifically, the silicon nitride material is etched selectively with respect to polysilicon. Accordingly, the polysilicon spacers 241 as well as the polysilicon pads 242, 243 are taken as an etching mask when etching the silicon nitride cap layer 21 for defining the word lines, the landing pads and the peripheral gate electrodes.

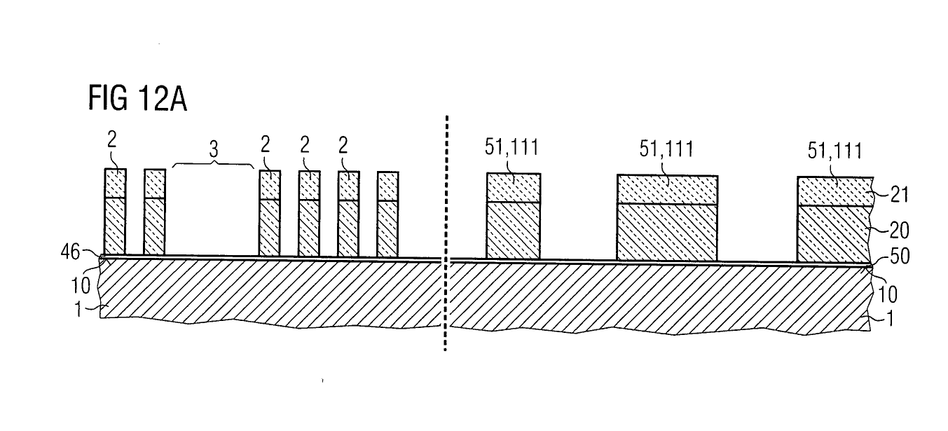

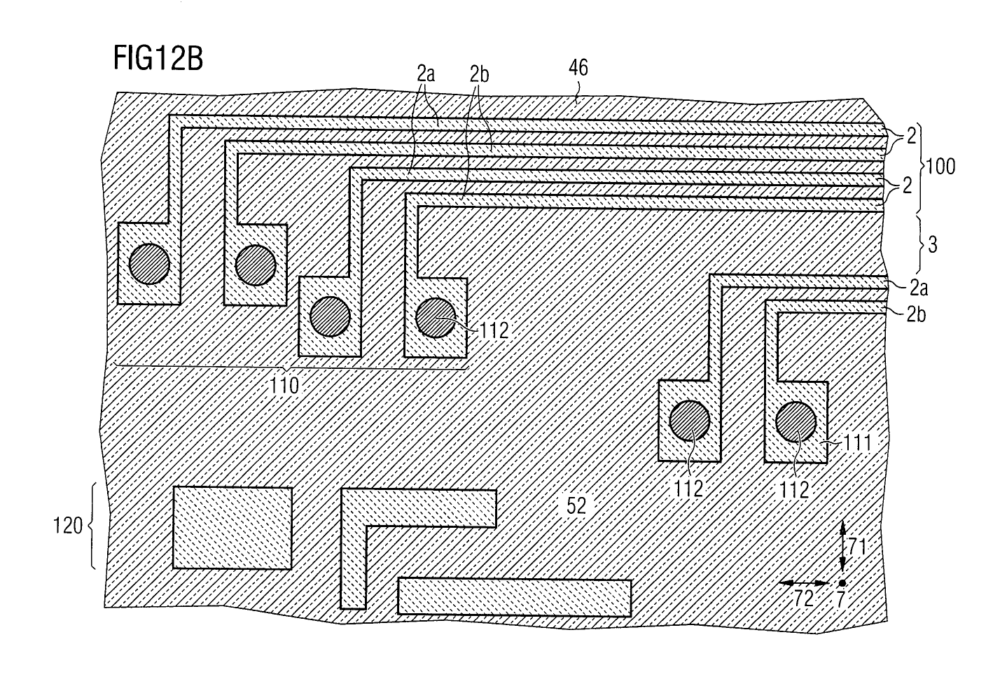

As can be seen from FIG. 11, in the array portion 100 as well as in the peripheral portion 120, layer stacks of the cap nitride layer 21, and the sacrificial layer 24 are patterned. Thereafter, an etching step for etching the word line layer stack is performed so that as a result single word lines 2 are formed in the array portion. FIG. 12A shows a cross-sectional view of the resulting structure. As can be seen, in the array portion 100, single word lines 2 are formed, with word line removal regions 3 being disposed at predetermined positions. In other words, the word line removal region 3 corresponds to an enlarged space between adjacent word lines 2. Moreover, in the peripheral portion, peripheral gate electrodes 51 are formed.

The step of etching the word line layer stack can be a single etching step of etching the entire layer stack. Optionally, the step of etching the word line layer stack may comprise several sub-steps in which only single layers or a predetermined number of layers are etched. In addition, after a sub-step of etching a predetermined number of layers, a liner layer may be deposited so as to protect an underlying layer of the layer stack against the etching.

FIG. 12B shows a plan view on the resulting structure. As can be seen, in the array portion 100, the single word lines 2 are protected by the cap nitride layer 21. In the fan-out region 110 landing pads 11 are formed, on which contact pads are positioned. Moreover, in the peripheral portion 120, the peripheral circuitry as is commonly used is formed. As will be apparent to the person skilled in the art, different arrangements of the landing pads 111 can be used so as to obtain an improved packaging density of the landing pads in the fan-out region 110.

As can further be seen from FIG. 12B the single word lines 2 are connected with the landing pads 111. The fan-out region 110 is isolated from the peripheral portion 120 by the silicon dioxide material 52. The contact pads 112 can be connected with a corresponding metal wiring in the following process step. Starting from the views shown in FIGS. 12A and 12B, the memory device will be completed in a manner as is known to the person skilled in the art. In particular, the peripheral portion of the memory device is completed. In addition, in the array portion, insulating layers comprising BPSG and SiO₂ layers are deposited, followed by the definition of bit line contacts in the word line removal region 3. In the MO wiring layer, conductive lines supporting the bit lines are provided, so that finally a completed memory device is obtained.

In the arrangement shown in FIG. 12B, the plurality of word lines comprises a first and a second subset of word lines. In particular, the word lines 2a of the first subset alternate with the word lines 2b of the second subset. As can be recognized, the landing pads which are connected with the word lines 2a of the first subset are disposed on the left hand side of the word lines, whereas the landing pads 111 which are connected with the word lines 2b of the second subset are disposed on the right hand side of the word lines. For example, the width of the word lines 2 can be less than 150 nm, optionally less than 100 nm or less than 60 nm, the width being measured along the first direction 71. The width of the word lines 2 can be equal to the width of the spaces isolating neighboring word lines. The width of the word lines 2 may as well be different from the width of the spaces.

The width of the landing pads may be less than 150 nm, the width being measured along the first direction 71. In addition, the length of the landing pads may be less than 150 nm, optionally less than 100 nm, the length being measured along the second direction 72.

As can be seen from FIG. 12B, the landing pads 111 are arranged in a staggered fashion with respect to the second direction. In particular, the landing pads are arranged with an increasing distance with reference to a reference position 7 of the memory device. In particular, the distance is measured along the second direction 72.

As can further be seen from FIG. 12B, two neighboring landing pads which are connected with two adjacent second conductive lines are disposed at the same height. In particular, the height is measured along the first direction with respect to the reference position 7 of the memory device. In the arrangement shown in FIG. 12B, the landing pads 111 are arranged on one side of the plurality of conductive lines.

Although the above description relates to a process flow for forming a memory device comprising a plurality of conductive lines, it is clearly to be understood that the present invention can be implemented in various manners. In particular, the array of conductive lines can be implemented with any kind of devices and, in addition, with any kind of memory devices which are different from the specific memory device explained above.

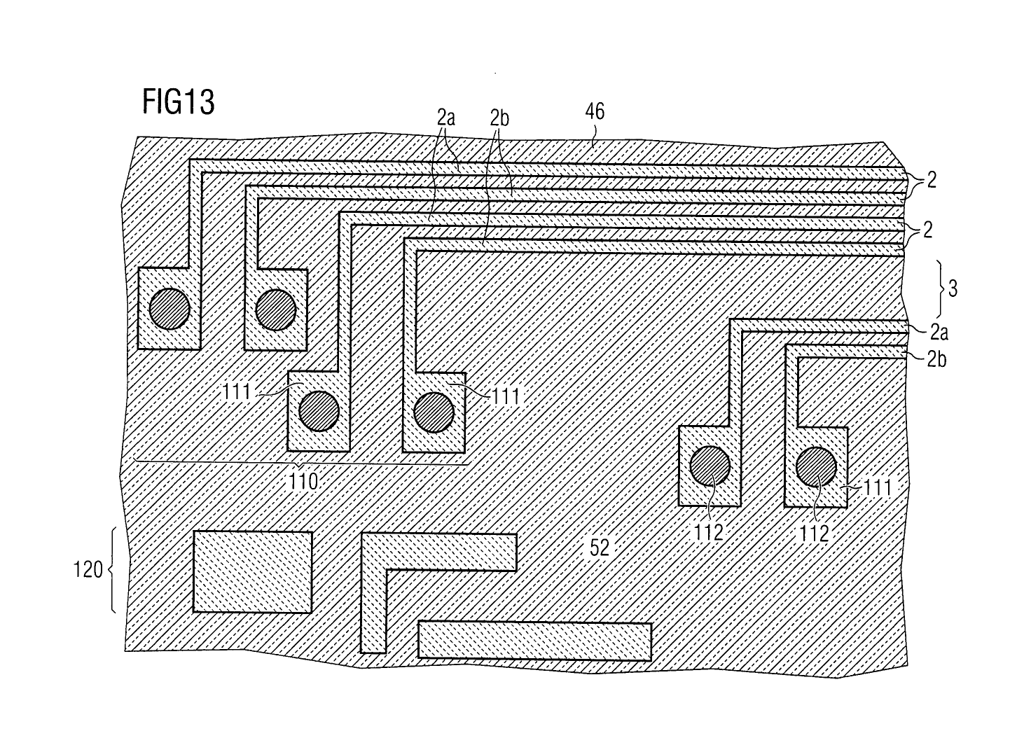

FIG. 13 shows a further embodiment of the memory device or the array of conductive lines of the present invention wherein the arrangement of the landing pads 111 is changed. According to this embodiment, a larger packaging density of the landing pads is achieved.

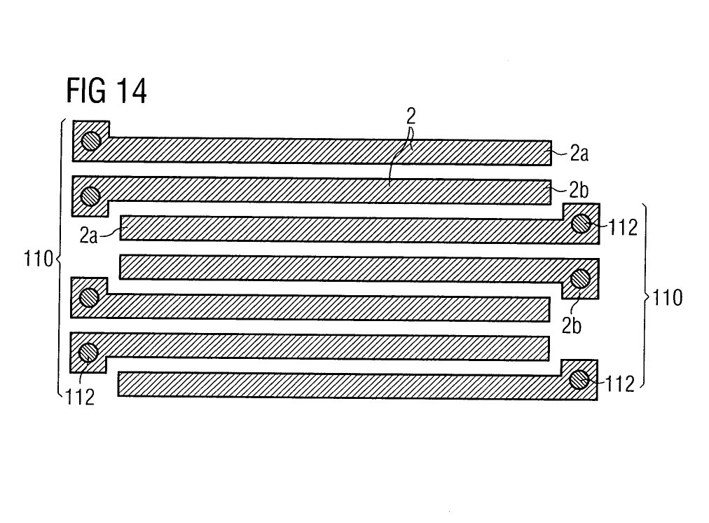

FIG. 14 shows an embodiment of the array of conductive lines or the memory device of the present invention. In particular, the landing pads 111 are disposed on either sides of the array of conductive lines.

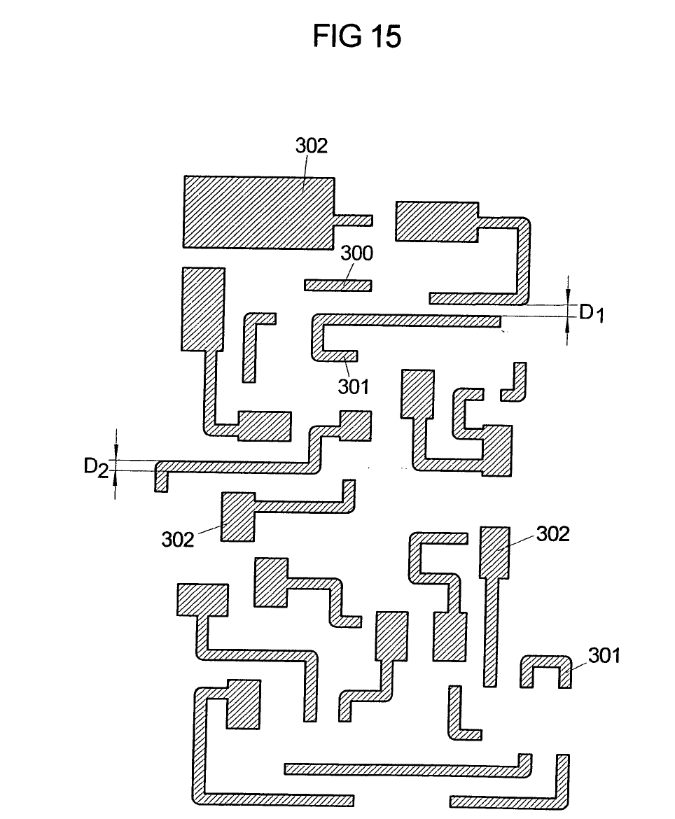

Another embodiment of the method according to the invention is used for the production of a semiconductor device with a more general structure, i.e., a structure which is not limited to regular patterns like an array depicted in FIG. 1A. An example of such a non-regular, i.e., random pattern is shown schematically in FIG. 15. The structure, which is, for example, a part of a microprocessor layout, comprises lines 300, lines with angles 301 and pads 302 resulting in a widening of lines 300. In other applications, such a structure could be part of a DRAM memory chip or another semiconductor device. In general, this example is to be understood as providing an embodiment of the invention that can be applied to non-regular patterns as well.

In FIG. 15, two exemplary areas are indicated in which the structure comprises widths below the resolution level of the lithographic process involved. On right hand side, a distance D₁ indicates that two line segments are only 30 nm apart. On the left hand side, it is indicated that a line width D₂ is 30 nm. Assuming that the employed lithography method can resolve 90 nm structures, the structure shown in FIG. 15 could not be produced without further measures. It is understood that the widths shown in FIG. 15 are exemplary only, since varying sublithograpic widths could be used in a layout. Furthermore, the lithographic resolution of 90 nm is only employed here by way of an example.

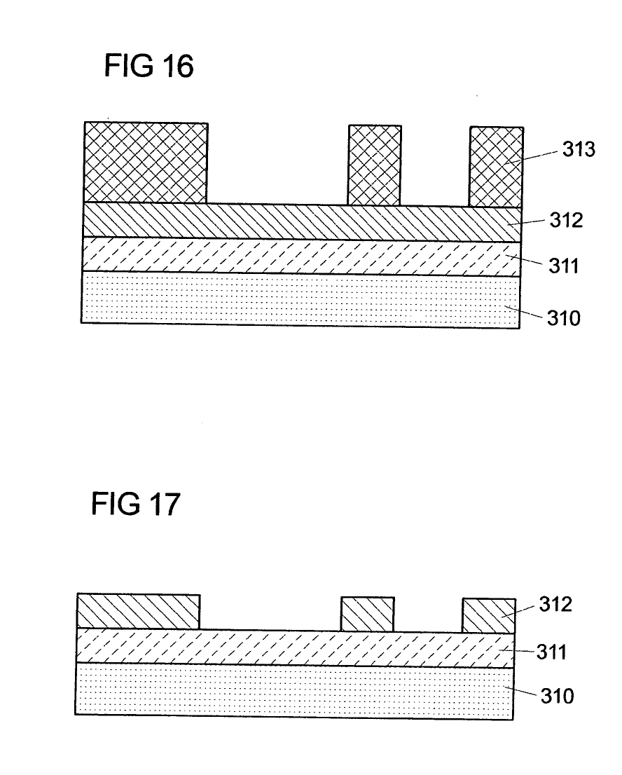

In the following, an embodiment of the method according to the invention is described with which those random (i.e., non-array like) sublithographic structures can be produced. The embodiment will be described in connection with a layered stack shown in a cross-section in FIG. 16. In principle, a stack as shown for example in FIG. 2 can be used. In this embodiment, FIG. 16 shows a somewhat more general structure which is positioned on a substrate, here a silicon substrate. In the silicon substrate, an arbitrary stack 310, e.g., a word line stack is positioned. On this stack, a first hardmask 311 and a second hardmask 312 are positioned. The first hardmask 311 is made of Si₃N₄, the second hardmask 312 is made of TEOS. Instead of TEOS, other SiO2 forms, such as BSG, can be used.

The materials for the hardmasks and the spacer can be interchanged. The second hardmask can comprise a carbon hardmask in connection with an additional SiON layer. Alternatively, the first hardmask may comprise a carbon hardmask and the second hardmask may comprises SiON. The spacer may comprise either polysilicon or TEOS. It is essential that the two hardmasks 311, 312 can be etched selectively. Therefore, it is understood that different materials pairings could be used for the hardmasks 311, 312. Alternatively, the first hardmask 311 could be a polysilicon layer, and the second hardmask 312 could be a Si₃N₄ layer.

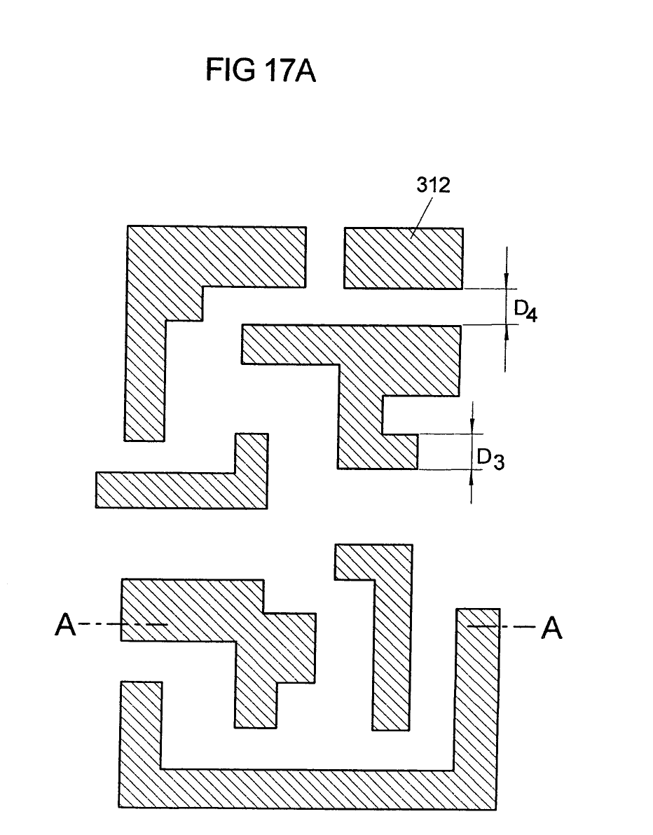

On top of the second hardmask, a photoresist layer 313 is deposited which already has been structured in a previous process step, which is not described here. In FIG. 17, the stack according to FIG. 16 is depicted after the second hardmask 312 has been structured by etching, e.g., by an anisotropic plasma ion etch. Subsequently, the photoresist layer 313 can be stripped. The stack depicted in FIG. 17 shows the second hardmask 312 having horizontal portions and vertical portions.

In FIG. 17A, the structured second hardmask 312 is shown in a top plan view (the underlying first hardmask 311 is not shown in this topview). The line A-A approximately indicates the cross-section depicted in FIG. 17. The smallest width D₃ in the second hardmask 312 is 90 nm in accordance with the employed lithographic method. Furthermore, the smallest gap D₄ between to sections of the second hardmask 312 is also 90 nm.

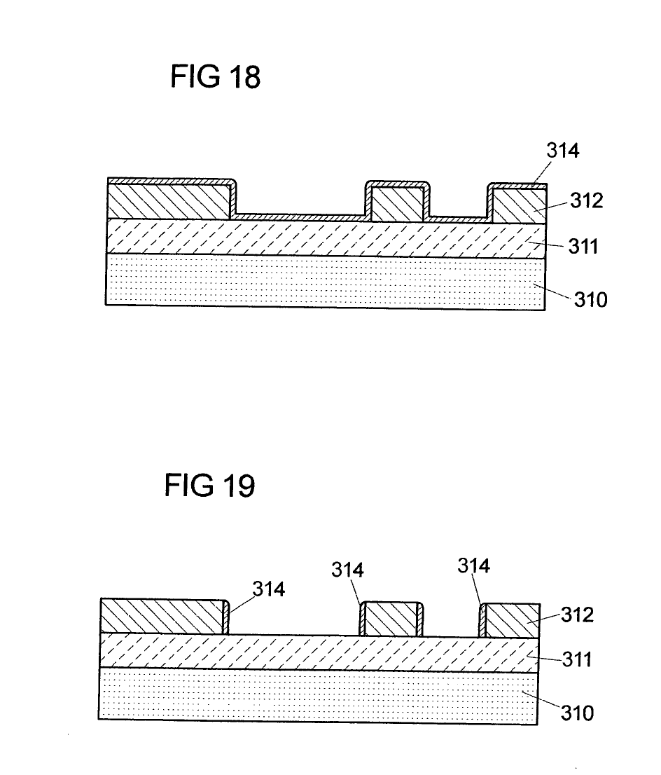

In the next process step, depicted in FIG. 18, a thin liner is conformally deposited as sacrificial layer 314 on top of the stack shown in FIG. 17. The thin liner 314 covers the horizontal as well as the vertical portions of the second hardmask 312. This sacrificial layer 314 is comparable to the sacrificial layer described in connection with FIG. 5. The material of the sacrificial layer 314 can be, for example, polysilicon. In principle, the sacrificial layer 314 can be any material, provided that it can be etched selectively to the material of the hardmasks 311, 312. Since the thin sacrificial layer 314 is later used in the structure, the thickness of the sacrificial layer 314 is chosen so that it conforms to the sublithographic design features to be achieved. Where, for example, the sublithographic feature should have a width of 30 nm, the sacrificial layer 314 should have a thickness of at least 40 nm.

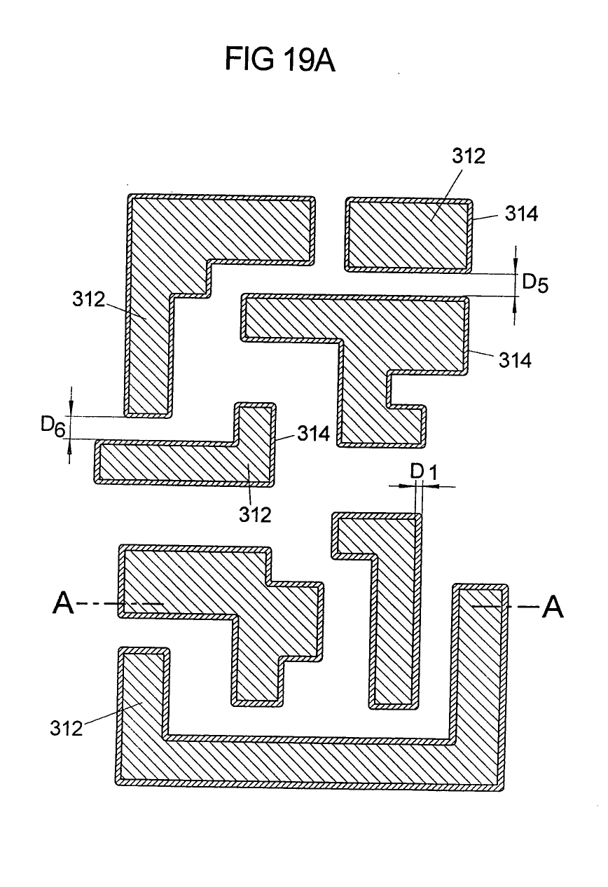

In FIG. 19, the stack of FIG. 18 is shown with the horizontal portion of the sacrificial layer 314 removed by spacer etching. The parameters of the plasma etch are adjusted so that the substantially horizontal portions are etched more than the vertical portions. The polysilicon material of the sacrificial layer 314 remains only on the vertical walls of the second hardmask 312.

In FIG. 19A, a top plan view of this situation is given, line A-A indicating the cross section of FIG. 19. The circumference of the second hardmask 312 areas are lined with the sacrificial material 314. The thickness D₅ of the sacrificial material is 30 nm. The smallest gap D₆ between the areas in FIG. 19A is also 30 nm, down from 90 nm in FIG. 17A. The original gap of 90 nm is narrowed by the sacrificial material 314 on both sides by 30 nm each.

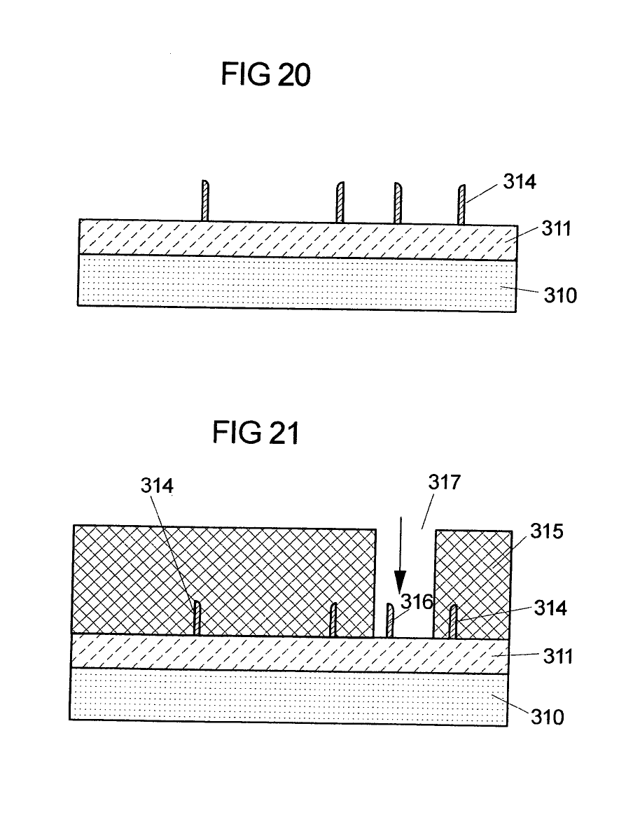

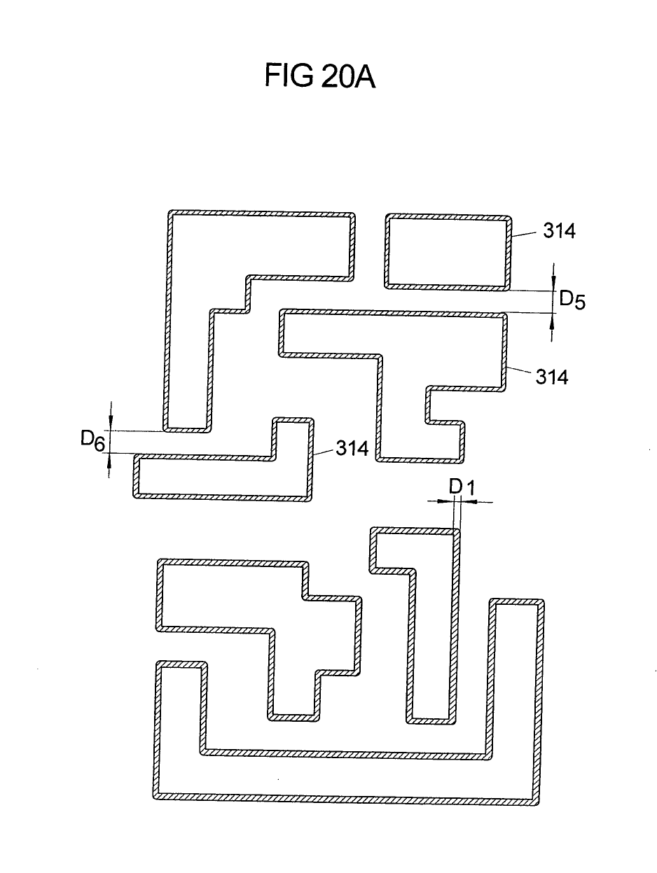

In the next process step, the remaining areas of the second hardmask 312 are removed by an anisotropic wet etch using chemistry with high selectivity. If the second hardmask 312 comprises Si₃N₄, hot phosphoric acid can be used. If the second hardmask 312 comprises SiO₂ buffered hydrofluoric acid can be used. As can be seen from FIG. 20, only the sacrificial material 314 remains on the first hardmask 311, the sacrificial material having a width of sub-resolution dimension.

In the top plan view of FIG. 20A, it can be seen that now a complex structure of thin, sublithographic lines has been produced which can be used to process the layers beneath sublithographically. Therefore, in the next process step, the layered stack, as shown in FIG. 20 is covered with a photoresist layer 315 and is structured in certain areas to remove some of the thin structures made of sacrificial material 314. The structuring of the photoresist layer 315 is performed with a normal lithographic procedure, e.g., with a 90 nm technology.

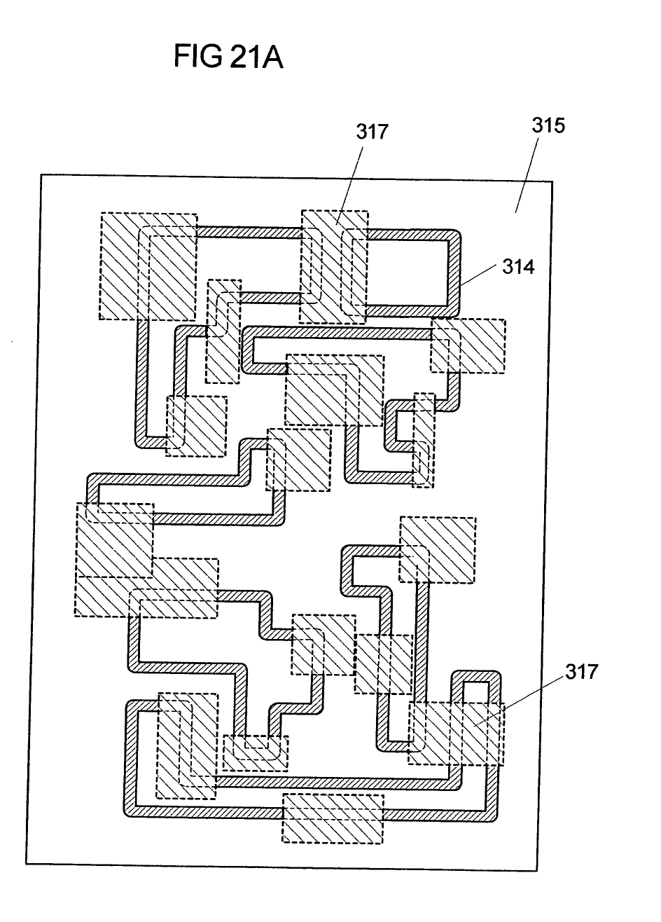

In FIG. 21, is depicted that a part of the photoresist 315 is opened in an area 317 so that one part 316 of the thin structure can be removed by etching. In principle dry and wet etching processes are possible. A wet etch process generally has a higher selectivity, but restrictions apply. Where, for example, the second hardmask comprises Si₃N₄, hot phosphoric acid cannot be used in the presence of a photoresist. The other thin structures in FIG. 21 are covered by the photoresist layer 315 and are consequently unaffected by the etching.

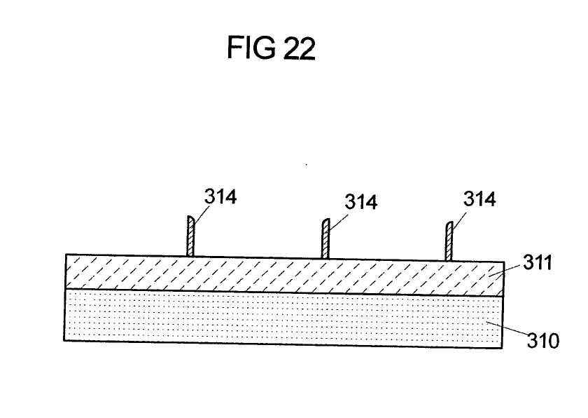

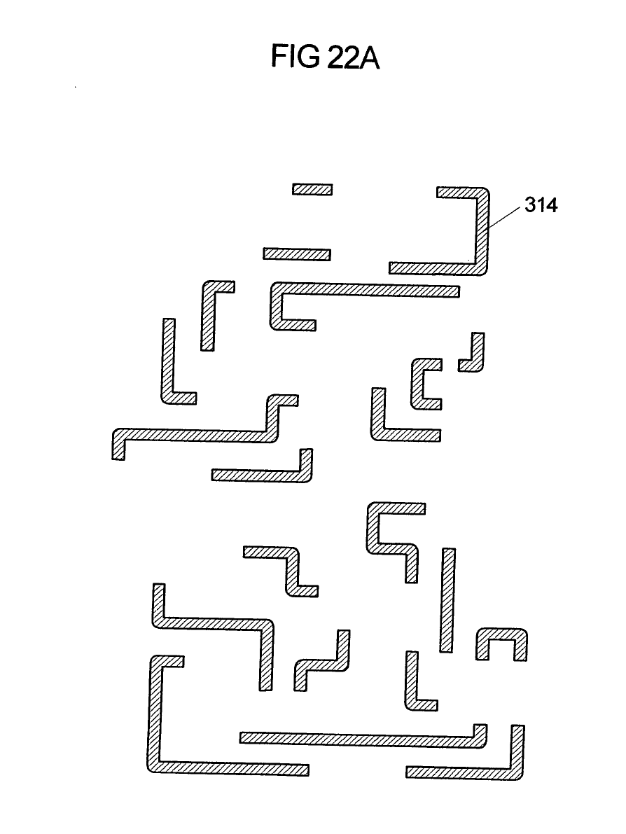

The effect of this is shown in the top plan view of FIG. 21A. Here, a plurality of areas 317 in which the photoresist layer 315 is opened is shown. Those areas 317 cut across certain parts of the thin structure made up by the sacrificial material 314. In FIG. 21A the sections of the thin structure 316 to be removed are indicated by dashed lines within the areas 317 to be opened in the photoresist 315. Using these openings 317, the thin structures 314 can be further patterned. The step shown in FIG. 21, 21A is a subtracting lithography step, since some parts of the thin structure 316 are removed. It should be noted that the removal of parts 316 of the thin structure could also be achieved by covering a stack as depicted in FIG. 19 with a photoresist layer and removing the thin structure 314 from the second hardmask 312 layer and then removing the second hardmask layer 312. In both cases the situation, as shown in FIG. 22, is reached.

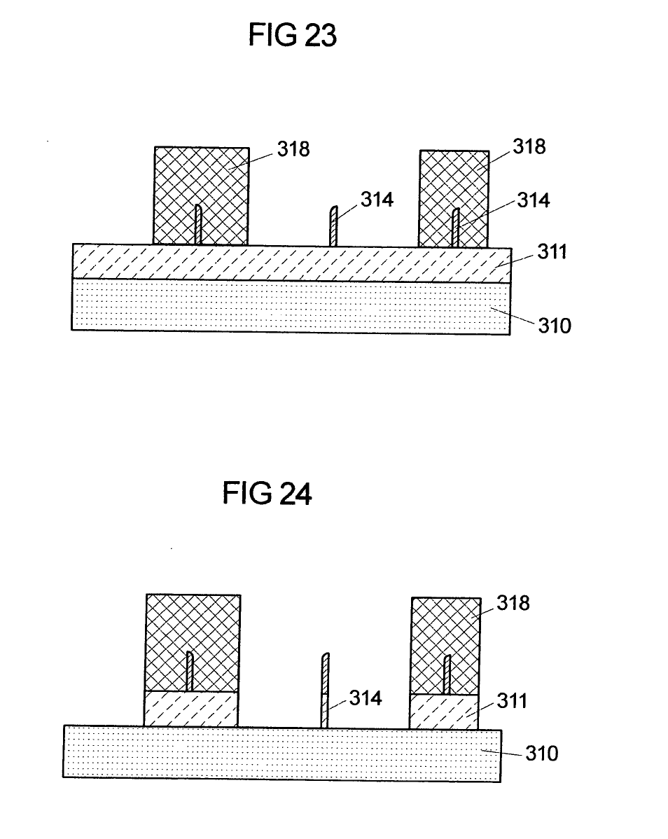

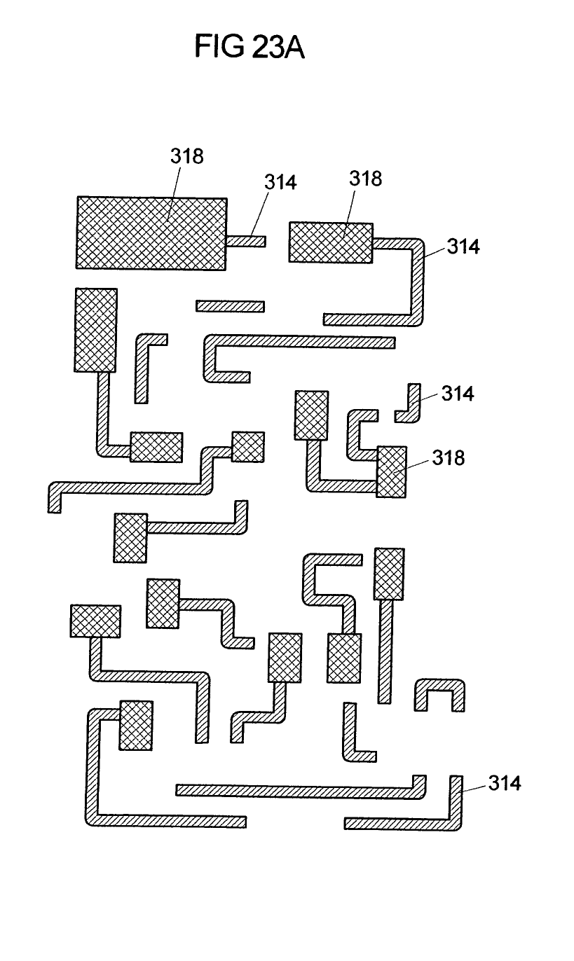

The result of the subtracting process step is shown in FIG. 22 in a cross sectional view. A better overview of the effect of the subtracting process step can be gained from FIG. 22A which shows the thin structures made of sacrificial material 314 with certain sections removed. If FIG. 22A is compared with FIG. 15, the result to be achieved, it is clear that certain material has to be added to the thin structures 314 made out of sacrificial material. To this effect a material adding step is performed (in some substeps) after the subtracting step, which ensures that the thin structures are widened in certain areas. Therefore, the layered stack according to FIG. 22 is covered with a further photoresist layer 318 which is then structured, covering part of the thin structure 314 made of sacrificial material (FIG. 23). The further photoresist 318 covers some of the thin structures 314 and parts of the first hardmask 311. The effect is best seen in FIG. 23A in which the photoresist covered areas 318 in some parts of the layout partly cover the thin structures 314.

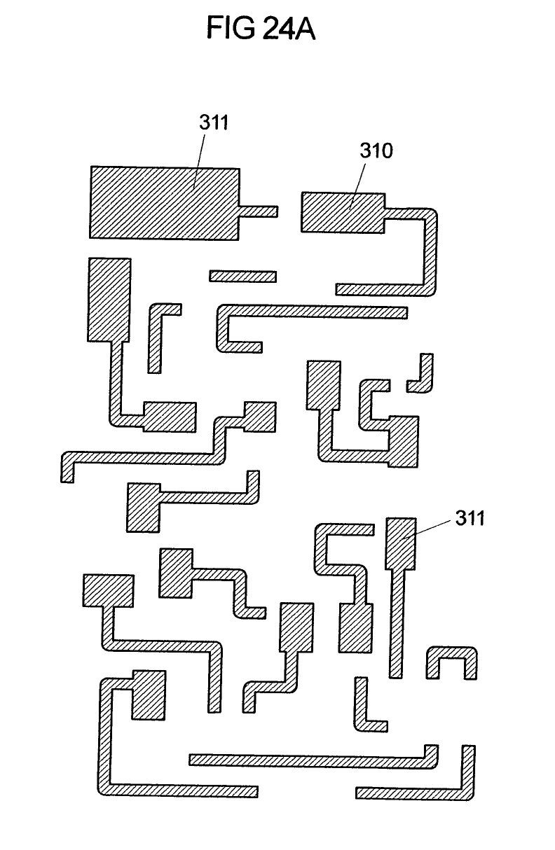

In the next process step, the stack according to FIG. 23 is etched, e.g., an anisotropic dry etch of first hardmask 311 selectively to the photoresist and the thin structure 314. In FIG. 24, it is shown that the photoresist 318 covers the first hardmask 311. The first hardmask 311 outside the further photoresist 318 is removed. The thin structure 314 is transferred into the first hardmask layer 311. Therefore, the first hardmask 311 is structured using the photoresist and the thin structure of sacrificial material.

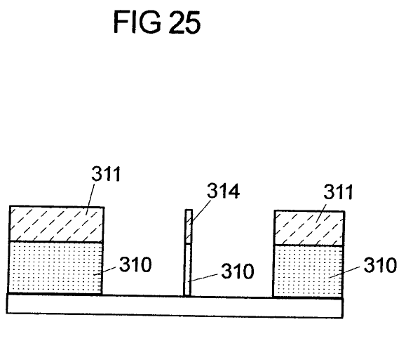

After stripping the photoresist 318 and removing the thin structures 314 made of sacrificial material, a structured first hardmask 311 remains (FIG. 25). In the top plan view of FIG. 25A, the first hardmask layer 311 is shown. The structure achieved is identical to the pattern in FIG. 15.

In FIGS. 15 to 25 an embodiment with one material subtracting and one material adding step is described using a thin liner layer to generate a thin structure 314 made of sacrificial material. It is understood that the step could be repeated to generate thin patterns of high density. Furthermore, the repeated use of sacrificial layer, e.g., with varying thickness can result in the manufacturing of patterns with differing width, e.g., lines in the range of 30 to 90 nm.

Having described preferred embodiments of the invention, it is believed that other modifications, variations and changes will be suggested to those skilled in the art in view of the teachings set forth herein. It is therefore to be understood that all such variations, modifications and changes are believed to fall within the scope of the present invention as defined by the appended claims. Although specific terms are employed herein, they are used in a generic and descriptive sense only and not for purposes of limitation.

What is claimed is:

1. A method for forming a structure of a semiconductor device, comprising:
providing a layer stack comprising a first hardmask layer over a substrate and a second hardmask over the first hardmask;
patterning the second hardmask layer to form a second hardmask structure having sidewalls;
conformally depositing a sacrificial layer of a sacrificial material such that the deposited sacrificial layer has substantially horizontal and vertical portions;
removing the horizontal portions of the sacrificial layer to form lines of the sacrificial material adjacent to the sidewalls of the second hardmask lines;
at least partially removing the sacrificial layer for structuring the sacrificial material and using the remaining sacrificial layer for structuring the first hardmask;
removing the second hardmask structures to uncover portions of the first hardmask; and
etching the uncovered portions of the layer stack thereby forming structures in the substrate.

2. The method according to claim 1, wherein the lines of the sacrificial material are at least partially cut due to the at least partial removing of the sacrificial layer.

3. The method according to claim 1, wherein the second hardmask layer is removed before at least partially removing the sacrificial layer.

4. The method according to claim 1, wherein structures of the sacrificial layer and the first hardmask are at least partially covered with a photoresist layer and the first hardmask and the structures in the sacrificial layer are etched using the photoresist layer as a mask to form a pattern in the first hardmask layer.

5. The method according to claim 4, wherein the pattern is used to form at least one of landing pads, lines, and logic transistors.

6. The method according to claim 1, wherein the thickness of the sacrificial layer is between 10 and 60 nm

7. The method according to claim 6, wherein the thickness of the sacrificial layer is between 30 and 50 nm.

8. The method according to claim 1, wherein the sacrificial layer comprises a material which can be selectively etched against the material of the first hardmask and the second hardmask.

9. The method according to claim 8, wherein the sacrificial layer comprises a material from the group of SiO₂ forms, BSG, silicon, polysilicon, and TEOS.

10. The method according to claim 1, wherein the first hardmask comprises a material from the group of Carbon, Si₃N₄, and polysilicon.

11. The method according to claim 1, wherein the second hardmask comprises a material from the group of SiO₂, TEOS, and Si₃N₄.

12. The method according to claim 1, wherein structuring of the sacrificial layer and structuring of the first hardmask are repeated at least once.

13. The method according to claim 12, wherein a plurality of spacers comprising sacrificial material is used to form structures with varying thickness.

14. The method according to claim 13, wherein the spacers have different thicknesses.
